(19) United States
(12) Patent Application Publication
(10) Pub. No.: US 2025/0240986 A1
(43) Pub. Date: Jul. 24, 2025

(54) CAPACITOR AND SEMICONDUCTOR DEVICE INCLUDING THE SAME

(71) Applicant: Samsung Electronics Co., Ltd., Suwon-si (KR)

(72) Inventors: Jeongil BANG, Suwon-si (KR); Haeryong KIM, Suwon-si (KR); Jaeho LEE, Suwon-si (KR); Jooho LEE, Suwon-si (KR)

(73) Assignee: Samsung Electronics Co., Ltd., Suwon-si (KR)

(21) Appl. No.: 19/003,504

(22) Filed: Dec. 27, 2024

(30) Foreign Application Priority Data
Jan. 22, 2024 (KR) 10-2024-0009793

(51) Int. Cl. H10D 1/68; H10B 12/00

(52) U.S. Cl. CPC H10D 1/684; H10B 12/31; H10D 1/716

(57) ABSTRACT

A capacitor includes a first electrode, a dielectric layer provided on the first electrode, an interface protection electrode provided on the dielectric layer such that the dielectric layer is between the first electrode and the interface protection electrode and including an oxide including Mo or V, and a second electrode provided on the interface protection electrode.

### CROSS-REFERENCE TO RELATED APPLICATION

This application is based on and claims priority under 35 U.S.C. § 119 to Korean Patent Application No. 10-2024-0009793, filed on Jan. 22, 2024, in the Korean Intellectual Property Office, the disclosure of which is incorporated by reference herein in its entirety.

### BACKGROUND

### 1. Field

The disclosure relates to a capacitor and a semiconductor device including the same.

### 2. Description of the Related Art

Semiconductor devices such as memory and transistors are used in various household and industrial devices. With the increasingly high performance of household and industrial devices, semiconductor devices have become highly integrated and miniaturized.

Along with the high integration and miniaturization of semiconductor devices, the sizes of semiconductor devices have decreased. Thus, the space occupied by capacitors included in (and/or as part of) the semiconductor devices is also shrinking. As the capacity of capacitors is based on the size of the capacitor, the capacity of capacitors decreases and leakage current increases due to the reduction in size of the capacitors; therefore various methods are proposed to solve such problems.

### SUMMARY

Provided are a capacitor with a reduced leakage current and an improved dielectric constant and a semiconductor device including the capacitor.

Additional aspects will be set forth in part in the description which follows and, in part, will be apparent from the description, or may be learned by practice of the presented embodiments of the disclosure.

According to an aspect of the disclosure, a capacitor includes a first electrode, a second electrode, a dielectric layer between the first electrode and the second electrode, and an interface protection electrode between the dielectric layer and the second electrode, the interface protection electrode including an oxide including molybdenum (Mo) or vanadium (V).

Space groups of the interface protection electrode and the dielectric layer may be shared as a tetragonal system.

Space groups of the interface protection electrode and the dielectric layer may be shared as a cubic system.

The lattice structure of the interface protection electrode and the lattice structure of the dielectric layer may share an oxygen atom with each other.

The interface protection electrode may include a plurality of layers.

The dielectric layer may include an oxide including a perovskite-type crystal structure.

The dielectric layer may include at least one of BaSrTiO₃ or SrTiO₃.

The dielectric layer may include a metal oxide including ZrO₂, HfO₂, TiO₂, Al₂O₃, or a combination thereof.

The dielectric layer may include a plurality of layers.

Among the plurality of layers of the dielectric layer, the layer directly contacting the interface protection electrode may include an oxide having a perovskite-type crystal structure.

The first electrode and the second electrode each may independently include a conductive material including at least one of titanium (Ti), nickel (Ni), aluminum (Al), tantalum (Ta), tungsten (W), platinum (Pt), palladium (Pd), gold (Au), iridium (Ir), rhodium (Rh), molybdenum (Mo), vanadium (V) or niobium (Nb), an oxide of Ti, an oxide of Ni, an oxide of Al, an oxide of Ta, an oxide of W, an oxide of Pt, an oxide of Pd, an oxide of Au, an oxide of Ir, an oxide of Rh, an oxide of Mo, an oxide of V or an oxide of Nb, a nitride of Ti, a nitride of Ni, a nitride of Al, a nitride of Ta, a nitride of W, a nitride of Pt, a nitride of Pd, a nitride of Au, a nitride of Ir, a nitride of Rh, a nitride of Mo, a nitride of V, or a nitride of Nb, or a combination thereof.

According to another aspect of the disclosure, a semiconductor device includes a transistor comprising a semiconductor substrate and a gate stack, the semiconductor substrate comprising a source region, a drain region, and a channel region between the source region and the drain region; and a capacitor electrically connected to the transistor, wherein the capacitor comprises a first electrode, a second electrode, a dielectric layer between the first electrode and the second electrode, and an interface protection electrode between the dielectric layer and the second electrode, the interface protection electrode comprising an oxide comprising molybdenum (Mo) or vanadium (V).

Space groups of the interface protection electrode and the dielectric layer may be shared as a tetragonal system.

Space groups of the interface protection electrode and the dielectric layer may be shared as a cubic system.

The lattice structure of the interface protection electrode and the lattice structure of the dielectric layer may share an oxygen atom with each other.

The dielectric layer may include an oxide including a perovskite-type crystal structure.

The dielectric layer may include at least one of BaSrTiO₃ or SrTiO₃.

The dielectric layer may include a metal oxide including ZrO₂, HfO₂, TiO₂, Al₂O₃, or a combination thereof.

The dielectric layer may include a plurality of layers, and among the plurality of layers, a layer contacting the interface protection electrode may include an oxide having a perovskite-type crystal structure.

The gate stack may be provided to face the channel region, on the semiconductor substrate, and include a gate insulating layer and a gate electrode.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view showing a schematic configuration of a capacitor according to at least one embodiment;

FIG. 2 is a conceptual diagram showing in detail an enlarged view of crystal structures of partial regions of a dielectric layer and an interface protection electrode included in the capacitor of FIG. 1;

FIG. 3 is a graph showing leakage current with respect to thickness of an equivalent oxide layer of capacitors according to at least one embodiment and a comparative example;

FIG. 4 is a transmission electron microscope (TEM) image of a cross-section of a capacitor according to at least one embodiment;

FIG. 5 is a TEM of a cross-section of a capacitor according to at least one embodiment;

FIG. 6 is a circuit diagram for describing a schematic circuit configuration and an operation of a semiconductor device employing a capacitor, according to at least one embodiment;

FIG. 7 is a view showing a semiconductor device according to at least one embodiment;

FIG. 8 is a view showing a semiconductor device according to at least one embodiment; and

FIGS. 9 and 10 are conceptual views schematically showing a device architecture applicable to a semiconductor device according to at least one embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, with reference to the accompanying drawings, a capacitor and a semiconductor device including the same according to various embodiments will be described in detail. In the drawings, like reference numerals denote like components, and sizes of components in the drawings may be exaggerated for convenience of explanation. In addition, embodiments to be described are merely examples, and various modifications may be made from such embodiments. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Additionally, whenever a range of values is enumerated, the range includes all values within the range as if recorded explicitly clearly, and may further include the boundaries of the range. Accordingly, the range of “X” to “Y” includes all values between X and Y, including X and Y.

An expression such as “above” or “on” may include not only the meaning of “immediately on in a contact manner”, but also the meaning of “on in a non-contact manner”. Singular forms include plural forms unless apparently indicated otherwise contextually. It will also be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly. When a portion is referred to as “comprises” a component, the portion may not exclude another component but may further include another component unless stated otherwise.

The use of the terms of “the above-described” and similar indicative terms may correspond to both the singular forms and the plural forms. When there is an explicit description of the order of operations of the method or there is no description contrary thereto, these operations may be performed in an appropriate order and the order is not necessarily limited to the described order.

Connections of lines or connection members between components shown in the drawings are illustrative of functional connections and/or physical or circuit connections, and in practice, may be represented as alternative or additional various functional connections, physical connections, or circuit connections. Also, in the specification, the term “units” or “ . . . modules” denote units or modules that process at least one function or operation, and may be realized by and/or include processing circuitry such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

The use of all examples or exemplary terms is only to describe technical spirit in detail, and the scope is not limited by these examples or terms unless limited by the claims.

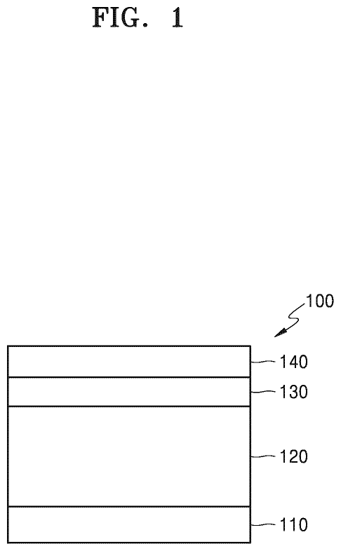

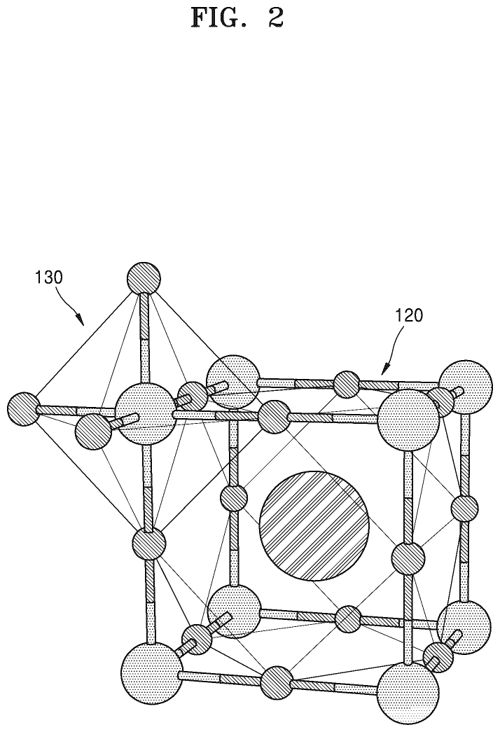

FIG. 1 is a cross-sectional view showing a schematic structure of a capacitor according to at least one embodiment, and FIG. 2 is a conceptual diagram showing in detail an enlarged view of crystal structures of partial regions of a dielectric layer and an interface protection electrode included in the capacitor of FIG. 1.

Referring to FIG. 1, a capacitor 100 may include a first electrode 110, a dielectric layer 120 provided on the first electrode 110, an interface protection electrode 130 provided on the dielectric layer 120 and including an oxide, and a second electrode 140 provided on the interface protection electrode 130.

The first electrode 110 may include a conductive material, such as a metal, a metal nitride, a metal oxide, and/or a combination thereof. For example, the first electrode 110 may include a metal (such as titanium (Ti), nickel (Ni), aluminum (Al), tantalum (Ta), tungsten (W), platinum (Pt), palladium (Pd), and gold (Au), iridium (Ir), rhodium (Rh), molybdenum (Mo), vanadium (V), niobium (Nb), etc.), a nitride of Ti, a nitride of Ni, a nitride of Al, a nitride of Ta, a nitride of W, a nitride of Pt, a nitride of Pd, a nitride of Au, a nitride of Ir, a nitride of Rh, a nitride of Mo, a nitride of V, a nitride of Nb, an oxide of Ti, an oxide of Ni, an oxide of Al, an oxide of Ta, an oxide of W, an oxide of Pt, an oxide of Pd, an oxide of Au, an oxide of Ir, an oxide of Rh, an oxide of Mo, an oxide of V, an oxide of Nb, etc., a combination thereof and/or the like. In at least one embodiment, the first electrode 110 may include a single material layer and/or a multilayer structure including a plurality of material layers.

The dielectric layer 120 may include an oxide having perovskite type crystal structure. The oxide having the perovskite type crystal structure may be, for example, a ternary compound expressed as a chemical equation of ABO₃. A may be arranged at eight corners of a unit cell, B may be arranged in the center of the unit cell, and an oxygen atom may be arranged in the center of six sides of the unit cell. In the unit cell, a ratio of A, B, and an oxygen atom may be 1:1:3. The dielectric layer 120 may include, for example, BaSrTiO₃ or SrTiO₃. The dielectric layer 120 may include a perovskite material including strontium (Sr), barium (Ba), titanium (Ti), hafnium (Hf), yttrium (Y), etc. However, the disclosure is not limited thereto, and the dielectric layer 120 may include various perovskite materials.

The dielectric layer 120 may include a metal oxide. The dielectric layer 120 may include a metal oxide including, for example, ZrO₂, HfO₂, TiO₂, Al₂O₃, or a combination thereof.

The dielectric layer 120 may have (or define) one or more structures. The structures may include, for example, a flat structure, a trench structure, and a pillar structure, but the disclosure is not limited thereto and any structure used in the art may be possible. As the dielectric layer 120 has this structure, the dielectric layer 120 is applicable to various types of devices.

The dielectric layer 120 may include a single layer or a plurality of layers. The dielectric layer 120 may include a 2-layer structure, a 3-layer structure, a 4-layer structure, etc., without being necessarily limited to such a range, and may have a multi-layer structure including more layers according to required performance. When the dielectric layer 120 includes a plurality of layers, a layer contacting the interface protection electrode 130 among the plurality of layers of the dielectric layer 120 may include an oxide having a perovskite-type crystal structure. For example, in at least one case (e.g., wherein the dielectric layer 120 includes a plurality of layers) at least one of the layers, other than the layer contacting the interface protection electrode 130, may include the metal oxide.

A thickness of the dielectric layer 120 may be, for example, at least about 10 Å but not more than about 100 Å. The thickness of the dielectric layer 120 may be, for example, within a range of about 20 Å to about 50 Å. When the thickness of the dielectric layer 120 is excessively small, a capacity of the capacitor per unit volume may decrease, but when the thickness of the dielectric layer 120 is excessively large, it may be difficult for the capacitor to satisfy a volume required by a memory device.

The interface protection electrode 130 may include an oxide. The interface protection electrode 130 may include an oxide including Mo and/or V. The interface protection electrode 130 may include, for example, MoO₂ or VO₂. However, the disclosure is not limited thereto, and the interface protection electrode 130 may include an oxide including Ni, Ta, Nb, and/or Fe.

An oxygen atom of the interface protection electrode 130 including an oxide including Mo, V, Ni, Ta, Nb, or Fe may spread to outside the interface protection electrode 130. As the oxygen atom of the interface protection electrode 130 spreads to the outside, the oxygen atom of the dielectric layer 120 may be prevented (and/or mitigated) from being lost to the outside. For example, without being limited to a specific theory, in at least one embodiment, the oxygen atom of the interface protection electrode 130 spreading to the outside may serve to replace an oxygen vacancy in the dielectric layer 120 and/or may introduce lattice strain in the interface between the interface protection electrode 130 and the dielectric layer 120, thereby increasing the energy required for the oxygen atom in the dielectric layer 120 to escape. In this way, the composition (and thereby the crystallinity) of the dielectric layer 120 may be maintained.

Even when the oxygen atom of the interface protection electrode 130 spreads to the outside, the interface protection electrode 130 may have high dielectric property and thus still serve as an electrode.

The interface protection electrode 130 may directly contact the dielectric layer 120. As shown in FIG. 2, space groups of the interface protection electrode 130 and the dielectric layer 120 may be shared as a tetragonal system. The space groups of the interface protection electrode 130 and the dielectric layer 120 may be shared as a cubic system. The interface protection electrode 130 and the dielectric layer 120 may share oxygen with each other. More specifically, as illustrated in FIG. 2, a lattice structure of the interface protection electrode 130 and of the dielectric layer 120 may share at least one oxygen atom with each other.

The interface protection electrode 130 may include a single layer or a plurality of layers. The interface protection electrode 130 may include a 2-layer structure, a 3-layer structure, a 4-layer structure, etc., without being necessarily limited to such a range, and may have a multi-layer structure including more layers according to required and/or desired performance.

The interface protection electrode 130 may directly contact the second electrode 140. The second electrode 140 directly contacting the interface protection electrode 130 may be an upper electrode as shown. The second electrode 140 may be separated from the first electrode 110 in a vertical direction. Herein, the upper electrode may mean that it is manufactured after the first electrode 110 at a manufacturing stage.

The second electrode 150 may include a conductive material. For example, the conductive material may be the same and/or a similar material as the first electrode 110. For example, the second electrode 140 may include a metal, a metal nitride, a metal oxide, or a combination thereof. The second electrode 140 may include, for example, a metal (such as titanium (Ti), nickel (Ni), aluminum (Al), tantalum (Ta), tungsten (W), platinum (Pt), palladium (Pd), gold (Au), iridium (Ir), rhodium (Rh), Molybdenum (Mo), vanadium (V), niobium (Nb), etc.), a nitride of Ti, a nitride of Ni, a nitride of Al, a nitride of Ta, a nitride of W, a nitride of Pt, a nitride of Pd, a nitride of Au, a nitride of Ir, a nitride of Rh, a nitride of Mo, a nitride of V, or a nitride of Nb, an oxide of Ti, an oxide of Ni, an oxide of Al, an oxide of Ta, an oxide of W, an oxide of Pt, an oxide of Pd, an oxide of Au, an oxide of Ir, an oxide of Rh, an oxide of Mo, an oxide of V, an oxide of Nb, etc., a combination thereof, and/or the like

The capacitor 100 according to at least one embodiment may include the interface protection electrode 130 to prevent the oxygen atom of the dielectric layer 120 from being lost to the outside, thereby suppressing formation of the dielectric layer 120 showing low dielectric characteristics. Moreover, as the space groups of the interface protection electrode 130 and the dielectric layer 120 are shared as a tetragonal system, the crystal structure of the dielectric layer 120 may not be destroyed and reduction of the leakage current and dielectric constant improvement of the capacitor 100 may be achieved at the same time.

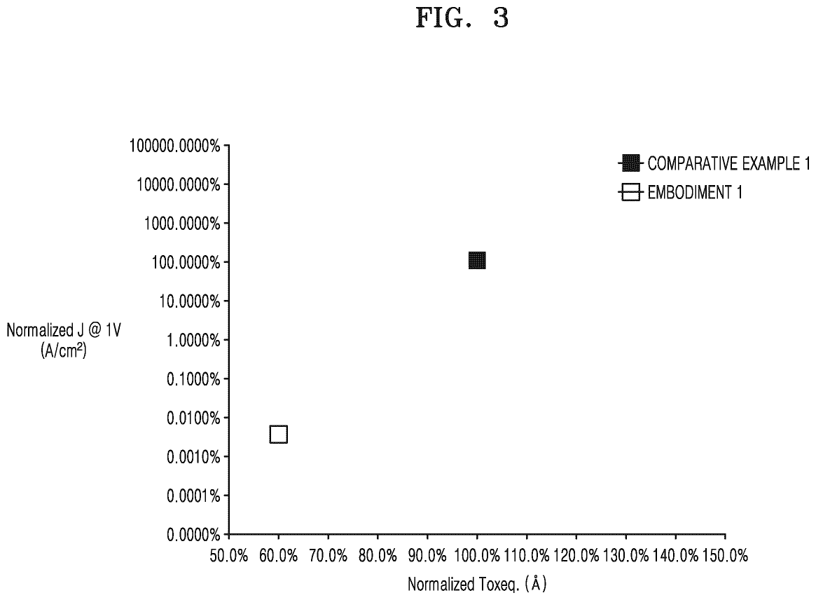

FIG. 3 is a graph showing leakage current with respect to thickness of an equivalent oxide layer of capacitors according to at least one embodiment and a comparative example.

### Comparative Example 1

Iridium (Ir) is provided as a first electrode. A dielectric layer of BaSrTiO₃ is formed on the first electrode, and a second electrode including platinum (Pt) is formed on the dielectric layer to manufacture a capacitor according to Comparative Example 1.

### Embodiment 1

Iridium (Ir) is provided as a first electrode. A dielectric layer including BaSrTiO₃ is formed on the first electrode, and an interface protection electrode including MoO₂ is formed on the dielectric layer. The second electrode including platinum (Pt) is formed on the interface protection electrode to manufacture a capacitor according to Embodiment 1.

Except that the interface protection electrode including MoO₂ is further formed, the capacitor according to Embodiment 1 is manufactured in the same manner as Comparative Example 1.

For the capacitor manufactured in Embodiment 1 and Comparative Example 1, a leakage current is measured for a thickness T_{oxeq} of an equivalent oxide layer, and a result is shown in FIG. 3. The leakage current is a current density when a voltage of 1V is applied to the capacitor, and a thickness of the dielectric layer is indicated as the thickness of the equivalent oxide layer.

In comparison to FIG. 3, the capacitor according to Embodiment 1 shows the thickness of the equivalent oxide layer having an improvement of about 40% and an about 5000 times lower leakage current density when compared to the capacitor according to Comparative Example 1. The capacitor according to Embodiment 1 exhibits better polarization of the dielectric layer than the capacitor according to Comparative Example 1. It may be seen that the capacitor according to Embodiment 1 exhibits a smaller equivalent oxide layer thickness (i.e., a higher dielectric constant) and a lower leakage current than the capacitor according to Comparative Example 1.

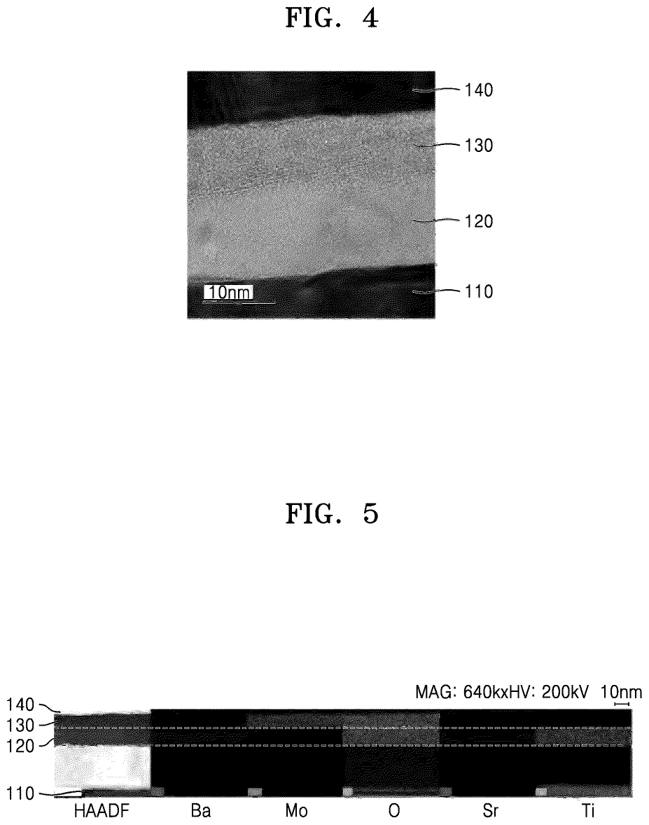

FIG. 4 shows a transmission electron microscope (TEM) image of a cross-section of a capacitor, according to at least one embodiment.

Referring to FIG. 4, the TEM image of the cross-section of the capacitor according to Embodiment 1 may be shown. It may be seen that an interface between the interface protection electrode 130 including MoO₂ and the second electrode 140 including Pt is uniformly formed, and an interface between the interface protection electrode 130 including MoO₂ and the dielectric layer 120 including BaSrTiO₃ is uniformly formed.

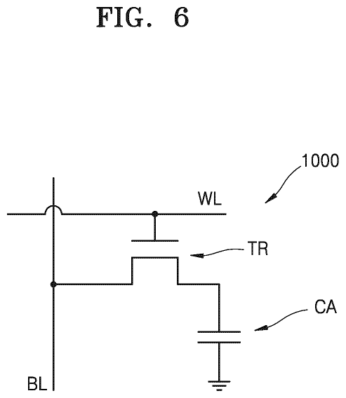

FIG. 5 is a TEM image of a cross-section of a capacitor according to at least one embodiment.

Referring to FIG. 5, an atom distribution per position of the capacitor according to Embodiment 1 is shown using high-angle annular dark field imaging (HAADF). In this way, it may be seen that the capacitor according to Embodiment 1 may include MoO₂ as the interface protection electrode 130 and BaSrTiO₃ as the dielectric layer 120. Both the interface protection electrode 130 and the dielectric layer 120 include oxygen.

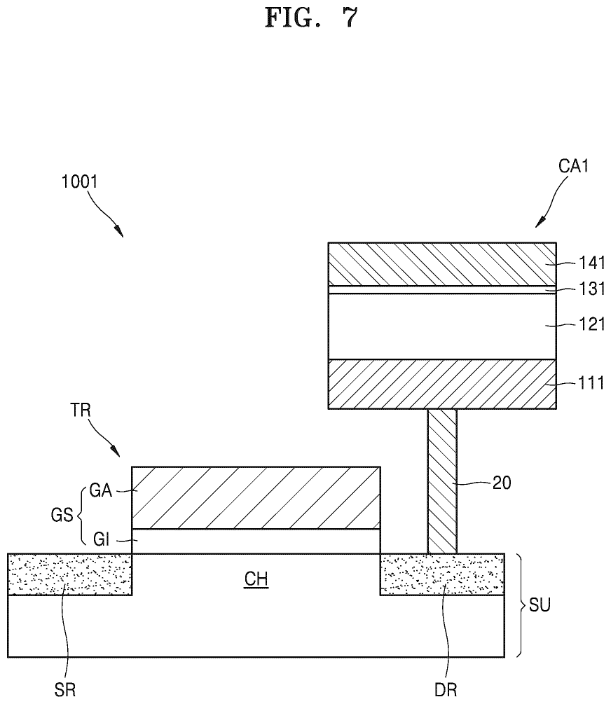

FIG. 6 is a circuit diagram for describing a schematic circuit configuration and an operation of a semiconductor device employing a capacitor, according to at least one embodiment.

A circuit diagram of a semiconductor device 1000 regards one cell of a memory device (e.g., a dynamic random access memory (DRAM) device), and includes one transistor TR, one capacitor CA, a word line WL, and a bit line BL. The capacitor CA may be the capacitor 100 described above with reference to FIG. 1, and thus the capacitor CA will not be described again.

A method to write data on a DRAM is as below. After a gate voltage (high) that turns the transistor TR into an ‘ON’ state is applied to a gate electrode through the word line WL, a data voltage VDD (high) or 0 (low) to be input to the bit line BL is applied. When the voltage (high) is applied to the word line and the bit line, the capacitor CA may be charged and data “1” may be recorded, and when the voltage (high) is applied to the word line and a voltage (low) is applied to the bit line, the capacitor CA may be discharged and data “0” may be recorded.

When data is read, the voltage (high) may be applied to the word line WL to turn ON the transistor TR of the DRAM and then a voltage of VDD/2 may be applied to the bit line BL. When data of the DRAM is “1”, that is, the voltage of the capacitor CA is VDD, charges in the capacitor CA may slowly move to the bit line BL such that the voltage of the bit line BL may become slightly higher than VDD/2. On the other hand, when the data of the capacitor CA is “0”, the charges of the bit line BL may move to the capacitor CA such that the voltage of the bit line BL may become slightly lower than VDD/2. An electric potential of the bit line, generated in this way, may be sensed and amplified by a sense amplifier, such that it may be determined whether corresponding data is “0” or “1”.

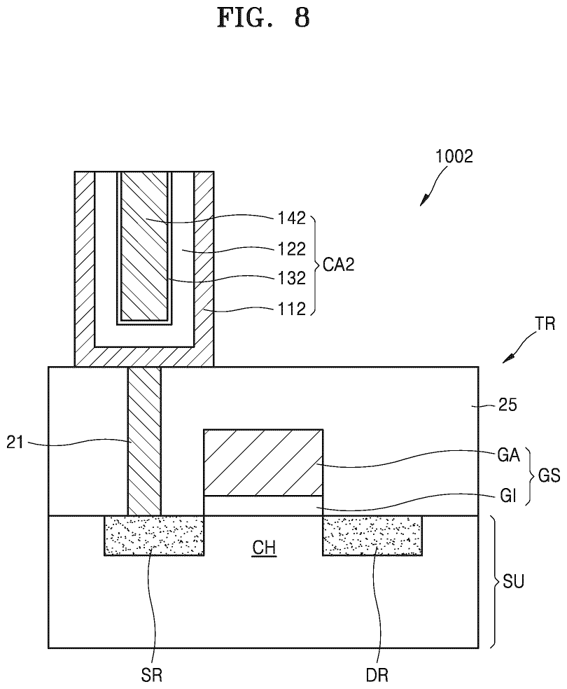

FIG. 7 is a view showing a semiconductor device according to at least one embodiment.

Referring to FIG. 7, in a semiconductor device 1001, a capacitor CA1 and a transistor TR may be electrically connected to each other by a contact 20. The capacitor CA1 may include a first electrode 111, a dielectric layer 121 provided on the first electrode 111, an interface protection electrode 131 provided on the dielectric layer 121 and including an oxide, and a second electrode 141 provided on the interface protection electrode 131. The capacitor CA may be the capacitor 100 described above with reference to FIG. 1, and the capacitor CA will not be described again.

The transistor TR may be a field effect transistor. The transistor TR may include a semiconductor substrate SU, which includes a source region SR, a drain region DR, and a channel region CH, and a gate stack GS, which is provided to face the channel region CH on the semiconductor substrate SU and includes a gate insulating layer GI and a gate electrode GA.

The channel region CH may be a region between the source region SR and the drain region DR and may be electrically connected to the source region SR and the drain region DR. The source region SR may be electrically connected to or contact an end of a side of the channel region CH, and the drain region DR may be electrically connected to or contact an end of the other side of the channel region CH. The channel region CH may be defined as a substrate region between the source region SR and the drain region DR in the semiconductor substrate SU.

The semiconductor substrate SU may include a semiconductor material. The semiconductor substrate SU may include a semiconductor material, for example, silicon (Si), germanium (Ge), silicon germanium (SiGe), silicon carbide (SiC), gallium arsenide (GaAs), indium arsenide (InAs), indium phosphide (InP), etc. The semiconductor substrate SU may include a silicon-on-insulator (SOI) substrate.

The source region SR, the drain region DR, and channel region CH may be independently formed by injecting impurities to different regions of the semiconductor substrate SU. In this case, the source region SR, the channel region CH, and the drain region DR may include a substrate material as a base material. The source region SR and the drain region DR may be formed of a conductive material. In this case, the source region SR and the drain region DR may include, for example, metal, a metal compound, a conductive polymer, and/or the like.

Unlike what is shown, the channel region CH may be implemented as a separate material layer (thin film). In this case, the channel region CH may include one or more of, for example, Si, Ge, SiGe, III-V semiconductors, oxide semiconductors, nitride semiconductors, oxynitride semiconductors, two-dimensional (2D) materials, quantum dots (QD), and organic semiconductors. The oxide semiconductor may include, for example, InGaZnO, etc. The 2D material may include, for example, transition metal dichalcogenide (TMD) or graphene. The QD may include, for example, a colloidal QD or nanocrystal structure.

The gate electrode GA may be separated from the semiconductor substrate SU to oppose the channel region CH on the semiconductor substrate SU. The gate electrode GA may include at least one of metal, a metal nitride, a metal carbide, and polysilicon. The metal may include at least one of, for example, aluminum (Al), tungsten (W), molybdenum (Mo), titanium (Ti), and tantalum (Ta). The metal nitride may include one or more of, for example, a titanium nitride (TiN) film and a tantalum nitride (TaN) film. The metal carbide may include one or more of, for example, aluminum and a silicon-doped (or contained) metal carbide. The metal carbide may include, for example, TiAlC, TaAlC, TiSiC, or TaSiC.

The gate electrode GA may have a structure in which a plurality of materials are stacked. For example, the gate electrode GA may have a stacked structure of a metal nitride layer/metal layer such as TiN/Al, etc., or a stacked structure of a metal nitride layer/metal carbide layer/metal layer such as TiN/TiAlC/W. The aforementioned materials used in the gate electrode GA are merely examples and the disclosure is not limited thereto.

A gate insulating layer GI may be further arranged between the semiconductor substrate SU and the gate electrode GA. The gate insulating layer GI may include a paraelectric material or a high-k dielectric material. The gate insulating layer GI may have a dielectric constant of, for example, about 20 to about 70.

The gate insulating layer GI may include a silicon oxide, a silicon nitride, an aluminum oxide, a hafnium oxide, a zirconium oxide, etc., and/or include a 2D insulator such as a hexagonal boron nitride (h-BN). The gate insulating layer GI may include, for example, a silicon oxide (SiO₂), a silicon nitride (SiNₓ), etc., and may include a hafnium oxide (HfO₂), a hafnium silicon oxide (HfSiO₄), a lanthanum oxide (La₂O₃), a lanthanum aluminum oxide (LaAlO₃), a zirconium oxide (ZrO₂), a hafnium zirconium oxide (HfZrO₂), a zirconium silicon oxide (ZrSiO₄), a tantalum oxide (Ta₂O₅)), a titanium oxide (TiO₂), a strontium titanium oxide (SrTiO₃), a yttrium oxide (Y₂O₃), aluminum oxide (Al₂O₃), a red scandium tantalum oxide (PbSc0.5Ta0.5O₃), red zinc niobate (PbZnNbO₃), etc. The gate insulating layer GI may include, for example, a metal nitride oxide such as an aluminum oxynitride (AlON), a zirconium oxynitride (ZrON), a hafnium oxynitride (HfON), a lanthanum oxynitride (LaON), an yttrium oxynitride (YON), etc., a silicate such as ZrSiON, HfSiON, YSiON, LaSiON, etc., or an aluminate such as ZrAlON, HfAlON, etc. The gate insulating layer GI may include, for example, the dielectric layer of the above-described capacitor. The gate insulating layer GI may constitute a gate stack together with the gate electrode GA.

One of the electrodes 111 and 141 of the capacitor CA1 and one of the source region SR and the drain region DR of the transistor TR may be electrically connected to each other by one contact 20. The contact 20 may include an appropriate conductive material, e.g., tungsten, copper, aluminum, polysilicon, etc.

An arrangement of the capacitor CA1 and the transistor TR may be changed variously. For example, the capacitor CA1 may be arranged on the semiconductor substrate SU, or may be buried in the semiconductor substrate SU.

FIG. 7 shows the semiconductor device 1001 including one capacitor CA1 and one transistor TR, but this illustration is merely an example and the semiconductor device 1001 may include a plurality of capacitors and a plurality of transistors.

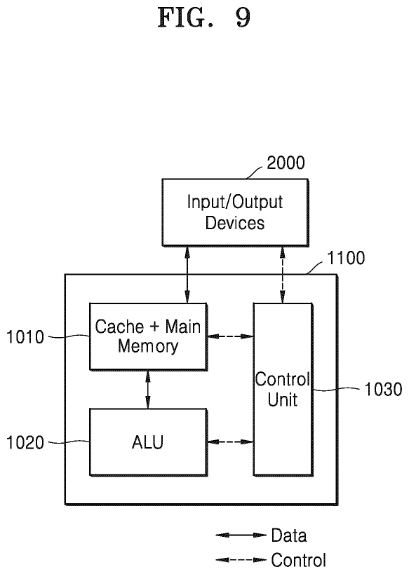

FIG. 8 is a view showing a semiconductor device according to at least one embodiment.

Referring to FIG. 8, in a semiconductor device 1002, a capacitor CA2 and the transistor TR may be electrically connected to each other by a contact 21.

The transistor TR may include the semiconductor substrate SU including the source region SR, the drain region DR, and the channel region CH therebetween, and the gate stack GS which is arranged to face the channel region CH on the semiconductor substrate SU and includes the gate insulating layer GI and the gate electrode GA.

An interlayer insulating film 25 may be provided to cover the gate stack GS on the semiconductor substrate SU. The interlayer insulating film 25 may include an insulating material. The interlayer insulating film 25 may include an Si oxide (e.g., SiO₂), an aluminum oxide (e.g., Al₂O₃), or a high-k dielectric material (e.g., HfO₂). The contact 21 may electrically connect the transistor TR to the capacitor CA1 through the interlayer insulating film 25.

The capacitor CA2 may include a first electrode 112, a dielectric layer 122 provided on the first electrode 112, an interface protection electrode 132 provided on the dielectric layer 121 and including an oxide, and a second electrode 142 provided on the interface protection electrode 132. The first electrode 112 and the second electrode 142 may be provided in a shape enlarging a contact area with the dielectric layer 122 to the maximum, and a material composition of the capacitor CA2 may be substantially the same as (or substantially similar to) the capacitor 100 described with reference to FIG. 1. For example, the first electrode 112 and the second electrode 142 may include a conductive material; the dielectric layer 122 may include an oxide having perovskite type crystal structure and/or a metal oxide; the interface protection electrode 132 may include an oxide including Mo, V, Ni, Ta, Nb, or Fe; and the dielectric layer 122 and the interface protection electrode 132 may be configured such that the interface protection electrode prevents (and/or mitigates) an oxygen atom of the dielectric layer 122 from escaping to the outside.

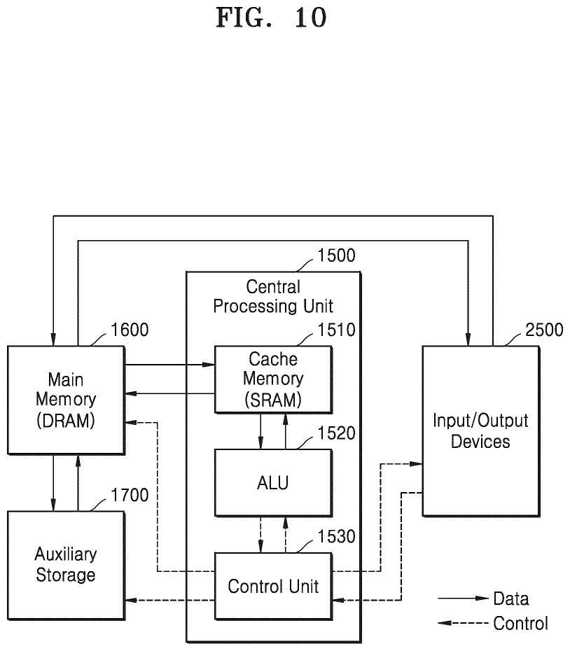

FIGS. 9 and 10 are conceptual views schematically showing a device architecture applicable to a semiconductor device according to at least one embodiment.

Referring to FIG. 9, an electronic device architecture 1100 may include a memory unit 1010, an arithmetic logic unit (ALU) 1020, and a control unit 1030. The memory unit 1010, the ALU 1020, and the control unit 1030 may be electrically connected to one another. The electronic device architecture 1100 may be implemented as one chip including, for example, the memory unit 1010, the ALU 1020, and the control unit 1030.

The memory unit 1010, the ALU 1020, and the control unit 1030 may communicate directly by being connected to one another through a metal line on-chip. The memory unit 1010, the ALU 1020, and the control unit 1030 may be monolithically integrated on one substrate to form one chip. An input/output device 2000 may be connected to the electronic device architecture (chip) 1100. The memory unit 1010 may include both a main memory and a cache memory. The electronic device architecture (chip) 1100 may be an on-chip memory processing unit. The memory unit 1010 may include the above-described capacitor and/or the semiconductor device using the same. The ALU 1020 or the control unit 1030 may also include the above-described capacitor and/or the semiconductor device using the same.

Referring to FIG. 10, a cache memory 1510, an ALU 1520, and a control unit 1530 may constitute a central processing unit (CPU) 1500, and the cache memory 1510 may include a static random access memory (SRAM). A main memory 1600 and an auxiliary storage 1700 may be included in addition to the CPU 1500, and an input/output device 2500 may also be included. The main memory 1600 may be, for example, a dynamic random access memory (DRAM), and may include the capacitor described with reference to FIG. 1.

Depending on a circumstance, the electronic device architecture may be implemented in a form where computing-unit devices and memory-unit devices are adjacent to each other in one chip, without distinction of sub-units.

The capacitor and the semiconductor device including the same according to the disclosure may include the interface protection electrode on the dielectric film, thereby having a high dielectric constant and superior leakage current preventing/reducing characteristics. While the capacitor and the semiconductor device including the same have been described with reference to the embodiments described in the drawings, it will be understood by those of ordinary skill in the art that various modifications and equivalent other embodiments are possible therefrom. Therefore, the disclosed embodiments should be considered in a descriptive sense rather than a restrictive sense. The scope of the present specification is not described above, but in the claims, and all the differences in a range equivalent thereto should be interpreted as being included.

According to a disclosed embodiment, by including an interface protection electrode on a dielectric film, a capacitor having a high dielectric constant and superior leakage current blocking/reducing characteristics may be provided.

The semiconductor device including the capacitor may easily implement high integration, contributing to miniaturization of the electronic device.

It should be understood that the example embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A capacitor comprising:
a first electrode;
a second electrode;
a dielectric layer between the first electrode and the second electrode; and
an interface protection electrode between the dielectric layer and the second electrode, the interface protection electrode comprising an oxide comprising molybdenum (Mo) or vanadium (V).

2. The capacitor of claim 1, wherein space groups of the interface protection electrode and the dielectric layer are shared as a tetragonal system.

3. The capacitor of claim 1, wherein space groups of the interface protection electrode and the dielectric layer are shared as a cubic system.

4. The capacitor of claim 1, wherein a lattice structure of the interface protection electrode and a lattice structure of the dielectric layer share an oxygen atom with each other.

5. The capacitor of claim 1, wherein the interface protection electrode comprises a plurality of layers.

6. The capacitor of claim 1, wherein the dielectric layer comprises an oxide comprising a perovskite-type crystal structure.

7. The capacitor of claim 6, wherein the oxide comprising the perovskite-type crystal structure comprises at least one of BaSrTiO₃ or SrTiO₃.

8. The capacitor of claim 1, wherein the dielectric layer comprises a metal oxide comprising ZrO₂, HfO₂, TiO₂, Al₂O₃, or a combination thereof.

9. The capacitor of claim 1, wherein the dielectric layer comprises a plurality of layers.

10. The capacitor of claim 9, wherein among the plurality of layers of the dielectric layer, a layer directly contacting the interface protection electrode comprises an oxide having a perovskite-type crystal structure.

11. The capacitor of claim 1, wherein the first electrode and the second electrode each independently comprise a conductive material including at least one of
titanium (Ti), nickel (Ni), aluminum (Al), tantalum (Ta), tungsten (W), platinum (Pt), palladium (Pd), gold (Au), iridium (Ir), rhodium (Rh), molybdenum (Mo), vanadium (V), niobium (Nb);
an oxide of Ti, an oxide of Ni, an oxide of Al, an oxide of Ta, an oxide of W, an oxide of Pt, an oxide of Pd, an oxide of Au, an oxide of Ir, an oxide of Rh, an oxide of Mo, an oxide of V, an oxide of Nb;
a nitride of Ti, a nitride of Ni, a nitride of Al, a nitride of Ta, a nitride of W, a nitride of Pt, a nitride of Pd, a nitride of Au, a nitride of Ir, a nitride of Rh, a nitride of Mo, a nitride of V, a nitride of Nb; or
a combination thereof.

12. A semiconductor device comprising:
a transistor comprising a semiconductor substrate and a gate stack, the semiconductor substrate comprising a source region, a drain region, and a channel region between the source region and the drain region; and
a capacitor electrically connected to the transistor,
wherein the capacitor comprises
a first electrode,
a second electrode,
a dielectric layer between the first electrode and the second electrode, and
an interface protection electrode between the dielectric layer and the second electrode, the interface protection electrode comprising an oxide comprising molybdenum (Mo) or vanadium (V).

13. The semiconductor device of claim 12, wherein space groups of the interface protection electrode and the dielectric layer are shared as a tetragonal system.

14. The semiconductor device of claim 12, wherein space groups of the interface protection electrode and the dielectric layer are shared as a cubic system.

15. The semiconductor device of claim 12, wherein a lattice structure of the interface protection electrode and a lattice structure of the dielectric layer share an oxygen atom with each other.

16. The semiconductor device of claim 12, wherein the dielectric layer comprises an oxide comprising a perovskite-type crystal structure.

17. The semiconductor device of claim 16, wherein the oxide comprising the perovskite-type crystal structure comprises at least one of BaSrTiO₃ or SrTiO₃.

18. The semiconductor device of claim 12, wherein the dielectric layer comprises a metal oxide comprising ZrO₂, HfO₂, TiO₂, Al₂O₃, or a combination thereof.

19. The semiconductor device of claim 12, wherein
the dielectric layer comprises a plurality of layers, and
among the plurality of layers of the dielectric layer, a layer directly contacting the interface protection electrode comprises an oxide having a perovskite-type crystal structure.

20. The semiconductor device of claim 12, wherein the gate stack comprises a gate insulating layer and a gate electrode and faces the channel region.
